(19) United States
(12) Patent Application Publication
(10) Pub. No.: US 2014/0189227 A1
(43) Pub. Date: Jul. 3, 2014

(54) MEMORY DEVICE AND A MEMORY MODULE HAVING THE SAME

(71) Applicant: SAMSUNG ELECTRONICS CO., LTD., Suwon-si (KR)

(72) Inventor: Jung-Hwan Choi, Hwaseong-si (KR)

(73) Assignee: SAMSUNG ELECTRONICS CO., LTD., Suwon-si (KR)

(21) Appl. No.: 14/072,195

(22) Filed: Nov. 5, 2013

Related U.S. Application Data
(60) Provisional application No. 61/746,690, filed on Dec. 28, 2012.

(30) Foreign Application Priority Data
Mar. 13, 2013 (KR) 10-2013-0026948

(51) Int. Cl. G11C 7/10

(52) U.S. Cl. CPC G11C 7/1072
USPC 711/105

(57) ABSTRACT

A memory device is provided. The memory device includes a plurality of memory chips, and a buffer chip connected to the plurality of memory chips. The plurality of memory chips and the buffer chip are disposed in a stack. A first input/output (IO) port of the buffer chip is connected in series to an external device, and a second IO port of the buffer chip is connected in parallel to IO ports of each of the plurality of memory chips.

### CROSS-REFERENCE TO RELATED APPLICATIONS

This application claims priority under 35 U.S.C. §120 to U.S. Patent Application No. 61/746,690 filed on Dec. 28, 2012, and claims priority under 35 U.S.C. §119 to Korean Patent Application No. 10-2013-0026948 filed on Mar. 13, 2013, the disclosures of which are incorporated by reference herein in their entireties.

### BACKGROUND

1. Technical Field

The inventive concept relates to a memory device and a memory module including the same, and more particularly, to a memory device embodied as a multi-chip package on which a plurality of dynamic random access memories (DRAMs) and a buffer chip are stacked, and a memory module including the same.

2. Discussion of the Related Art

An increase in the capacity or operating frequency of a memory module may improve the performance of a memory system. For example, an increase in the operating frequency of a data bus connected to the memory module may improve the performance of the memory system, and similarly the connection of a plurality of memories in parallel to the data bus may improve the performance of the memory system. However, the increase in the operating frequency of the data bus is physically limited by a capacitive load at input terminals of the plurality of memories connected in parallel to the data bus.

### SUMMARY

Exemplary embodiments of the inventive concept provide a memory device capable of reducing a capacitive load in a memory system in which a plurality of memory modules are installed.

Exemplary embodiments of the inventive concept provide a memory module including a plurality of memory devices.

In accordance with an exemplary embodiment of the inventive concept, a memory device includes a plurality of memory chips, and a buffer chip connected to the plurality of memory chips. The plurality of memory chips and the buffer chip are disposed in a stack. A first input/output (IO) port of the buffer chip is connected in series to an external device. A second IO port of the buffer chip is connected in parallel to IO ports of each of the plurality of memory chips.

In an exemplary embodiment of the inventive concept, at least one of the memory chips may include a dynamic random access memory (DRAM), the DRAM and the buffer chip may be memory chips manufactured according to the same memory manufacturing process, and the buffer chip may include a failed memory cell region.

In an exemplary embodiment of the inventive concept, the buffer chip may include eight IO buffers, and each of the eight IO buffers may be connected to an e-fuse configured to electrically isolate the failed memory cell region.

In an exemplary embodiment of the inventive concept, at least one of the memory chips may include first to eighth data queues each connected to a respective one of eight IO buffers of the memory chip, and the buffer chip comprises first to eighth data queues each connected to a respective one of the eight IO buffers of the buffer chip.

In an exemplary embodiment of the inventive concept, the external device may include a memory controller. The first to fourth data queues of the buffer chip may be connected to the memory controller. The fifth data queue of the buffer chip may be connected to a first data queue of each of the plurality of memory chips. The sixth data queue of the buffer chip may be connected to a second data queue of each of the plurality of memory chips. The seventh data queue of the buffer chip may be connected to a third data queue of each of the plurality of memory chips. The eighth data queue of the buffer chip may be connected to a fourth data queue of each of the plurality of memory chips.

In an exemplary embodiment of the inventive concept, the buffer chip may further include a first anti-fuse configured to electrically connect the IO buffers of the buffer chip connected to the first and fifth data queues of the buffer chip, a second anti-fuse configured to electrically connect the IO buffers of the buffer chip connected to the second and sixth data queues of the buffer chip, a third anti-fuse configured to electrically connect the IO buffers of the buffer chip connected to the third and seventh data queues of the buffer chip, and a fourth anti-fuse configured to electrically connect the IO buffers of the buffer chip connected to the fourth and eighth data queues of the buffer chip.

In an exemplary embodiment of the inventive concept, the IO buffers of the buffer chip may be normally operable.

In an exemplary embodiment of the inventive concept, each of the plurality of memory chips may be connected to the external device via the buffer chip.

In accordance with an exemplary of the inventive concept, a memory module includes a plurality of memory devices, wherein at least one of the plurality of memory devices includes a plurality of memory chips and a buffer chip connected to the plurality of memory chips. The plurality of memory chips and the buffer chip are disposed in a stack. A first input/output (IO) port of the buffer chip is connected in series to an external device, and a second IO port of the buffer chip is connected in parallel to IO ports of each of the plurality of memory chips.

In an exemplary embodiment of the inventive concept, at least one of the memory chips may include a DRAM. The DRAM and the buffer chip may be memory chips manufactured according to the same memory manufacturing process. The buffer chip may include a failed memory cell region.

In an exemplary embodiment of the inventive concept, the buffer chip may include eight IO buffers, and each of the eight IO buffers may be connected to an e-fuse configured to electrically isolate the failed memory cell region.

In an exemplary embodiment of the inventive concept, at least one of the memory chips may include first to eighth data queues each connected to a respective one of eight IO buffers of the memory chip, and the buffer chip comprises first to eighth data queues each connected to a respective one of the eight IO buffers of the buffer chip.

In an exemplary embodiment of the inventive concept, the external device comprises a memory controller. The first to fourth data queues of the buffer chip may be connected to the memory controller. The fifth data queue of the buffer chip may be connected to a first data queue of each of the plurality of memory chips. The sixth data queue of the buffer chip may be connected to a second data queue of each of the plurality of memory chips. The seventh data queue of the buffer chip may be connected to a third data queue of each of the plurality of memory chips. The eighth data queue of the buffer chip may be connected to a fourth data queue of each of the plurality of memory chips.

In an exemplary embodiment of the inventive concept, the memory device may be a multi-chip package.

In an exemplary embodiment of the inventive concept, the memory module may include a registered dual in-line memory module (RDIMM) or a load-reduced dual in-line memory module (LRDIMM).

In accordance with an exemplary embodiment of the inventive concept, a memory device includes a stacked structured including a plurality of memory chips and a buffer chip, wherein the buffer chip includes a first plurality of data queues configured to be connected to an external device and a second plurality of data queues connected to data queues of each of the plurality of memory chips.

The external device is a memory controller.

The memory chips include a DRAM.

The second plurality of data queues of the buffer chip includes first to fourth data queues, and each of the first to fourth data queues is connected to a respective data queue of each of the plurality of memory devices.

The buffer chip includes a failed memory cell region.

### BRIEF DESCRIPTION OF THE DRAWINGS

The foregoing and other features and of the inventive concept will become more apparent by describing in detail exemplary embodiments thereof with reference to the accompanying drawings in which:

FIG. 1 is a block diagram of a memory module in accordance with an exemplary embodiment of the inventive concept;

FIG. 2 illustrates a general dual in-line memory module (DIMM);

FIG. 3 illustrates the inside of a memory device of FIG. 1, according to an exemplary embodiment of the inventive concept;

FIG. 4 illustrates a wafer including the memory device of FIG. 3, according to an exemplary embodiment of the inventive concept;

FIG. 5 is a block diagram of a memory system in accordance with an exemplary embodiment of the inventive concept;

FIG. 6 is a diagram of a buffer chip of FIG. 5, according to an exemplary embodiment of the inventive concept;

FIGS. 7A to 7D are diagrams illustrating a data input/output structure of the memory device of FIG. 4, according to an exemplary embodiment of the inventive concept;

FIG. 8 is a diagram of a main board including the memory module of FIG. 1 in accordance with an exemplary embodiment of the inventive concept;

FIG. 9 is a block diagram of a computer system including the memory device of FIG. 3 in accordance with an exemplary embodiment of the inventive concept;

FIG. 10 is a block diagram of a computer system including the memory device of FIG. 3 in accordance with an exemplary embodiment of the inventive concept; and

FIG. 11 is a block diagram of a computer system including the memory device of FIG. 3 in accordance with an exemplary embodiment of the inventive concept.

### DETAILED DESCRIPTION OF THE EMBODIMENTS

Hereinafter, exemplary embodiments of the inventive concept will be described in detail with reference to the accompanying drawings. However, the inventive concept may be embodied in various different forms, and should not be construed as being limited to the illustrated embodiments.

It will be understood that when an element or layer is referred to as being “connected to,” or “coupled to” another element or layer, it can be directly connected or coupled to the other element or layer, or intervening elements or layers may be present.

As used herein, the singular forms “a,” “an,” and “the” are intended to include the plural forms as well, unless the context clearly indicates otherwise.

Like reference numerals may refer to like elements throughout the specification and drawings.

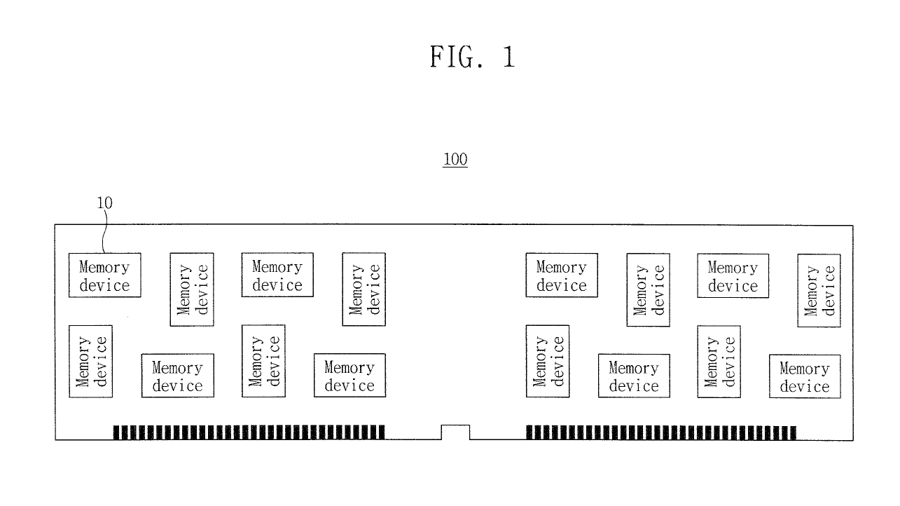

FIG. 1 is a block diagram of a memory module 100 in accordance with an exemplary embodiment of the inventive concept.

Referring to FIG. 1, the memory module 100 may include sixteen memory devices 10. Each of the sixteen memory devices 10 may be capable of inputting and outputting data in units of 4 bits. Thus, 64-bit data may be input to or output from the memory module 100. In an exemplary embodiment of the inventive concept, the memory module 100 may be a registered dual in-line memory module (RDIMM) or a load-reduced dual in-line memory module (LRDIMM).

In general, the memory module 100 is referred to as a single in-line memory module (SIMM) when the memory devices 10 are mounted on one surface of the memory module 100, and is referred to as a dual in-line memory module (DIMM) when the memory devices 10 are mounted on both surfaces of the memory module 100. A surface of the memory module 100 on which a plurality of memory devices 10 are mounted, is generally referred to as a rank.

Examples of the memory module 100 may include a small outline DIMM (SO-DIMM) and a micro-DIMM which may be used in notebook computers, a DIMM which may be used in personal computers, a RDIMM and a LRDIMM which may be used in servers, etc.

Referring back to FIG. 1, the memory device 10 may be a multi-chip package on which a plurality of dynamic random access memories (DRAMs) are stacked to increase memory capacity. A case in which the memory device 10 is a multi-chip package will be described in detail with reference to FIG. 3 below.

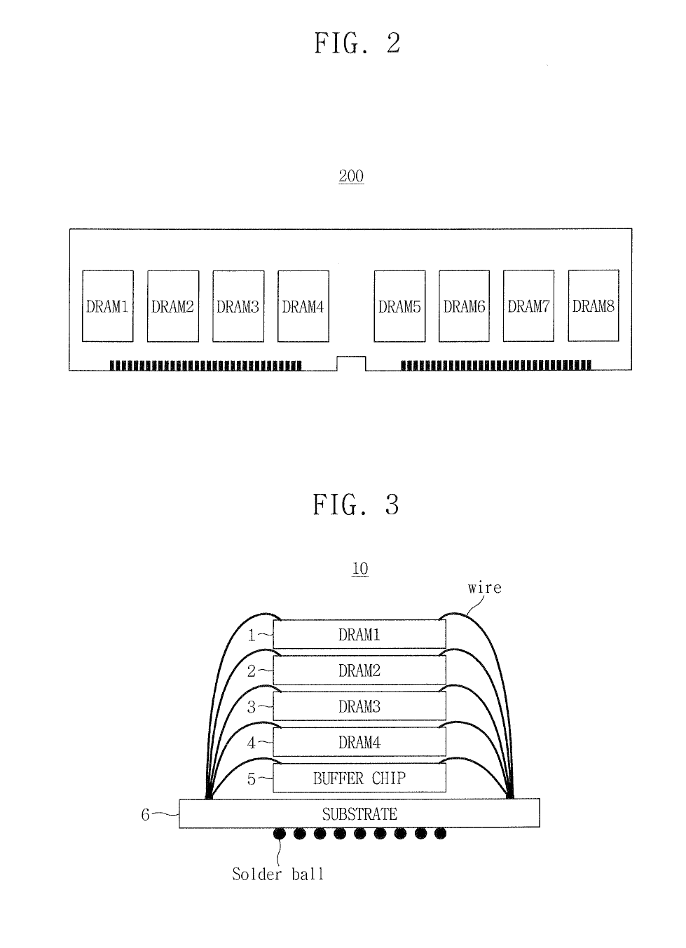

FIG. 2 illustrates a general DIMM 200.

Referring to FIG. 2, the DIMM 200 may include eight DRAMs. The first to eighth DRAMs may each include 8-bit data queues. Thus, 64-bit data may be input to or output from the DIMM 200.

In contrast, the memory module 100 of FIG. 1 in accordance with an exemplary embodiment of the inventive concept may include sixteen DRAMs. For example, the memory module 100 may be a LRDIMM. The sixteen DRAMs of the memory module 100 may each include 8-bit data queues, but use only 4-bit data queues among the 8-bit data queues. Accordingly, both data that may be input to or output from the DIMM 200 and data that may be input to or output from the memory module 100 in accordance with an exemplary embodiment of the inventive concept, may be 64 bits long.

FIG. 3 illustrates the inside of the memory device 10 of FIG. 1, according to an exemplary embodiment of the inventive concept.

Referring to FIG. 3, the memory device 10 may be a multi-chip package. The memory device 10 may be formed by stacking a plurality of memory chips and a buffer chip. In an exemplary embodiment of the inventive concept, the memory chips may be DRAMs.

In detail, the memory device 10 may include a first DRAM 1 to a fourth DRAM 4, a buffer chip 5 configured to connect each of the first DRAM 1 to the fourth DRAM 4 to an external memory controller (not shown), and a substrate 6 on which the first DRAM 1 to the fourth DRAM 4 and the buffer chip 5 are stacked.

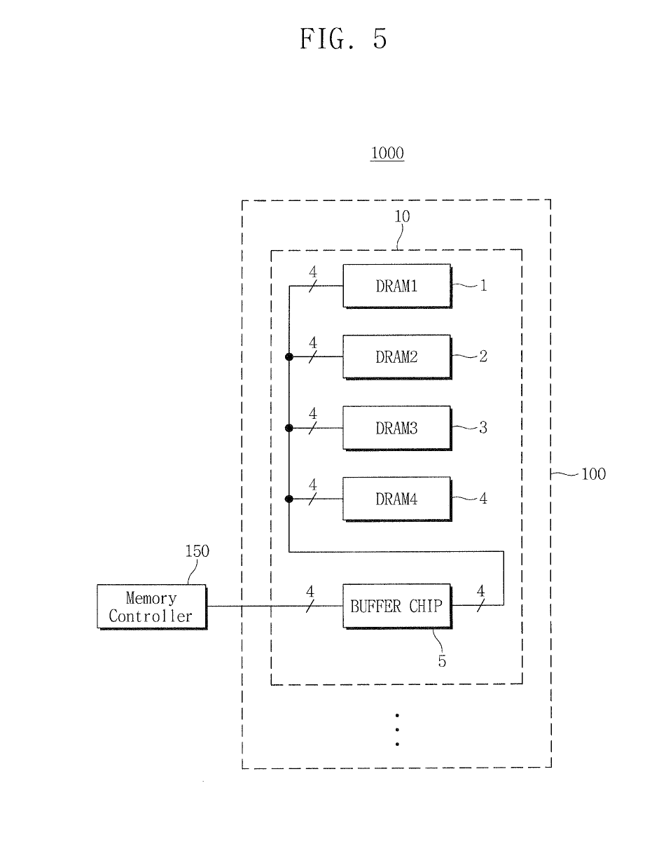

The first DRAM 1 to the fourth DRAM 4 and the buffer chip 5 may be connected to the substrate 6 via wires. The first DRAM 1 to the fourth DRAM 4 and the buffer chip 5 may be stacked on a top surface of the substrate 6. A method of connecting the first DRAM 1 to the fourth DRAM 4 and the buffer chip 5 to one another will be described in detail with reference to FIGS. 5 to 7D below.

Solder balls may be mounted on a bottom surface of the substrate 6 to connect the substrate 6 to an external host, e.g., a memory controller. In an exemplary embodiment of the inventive concept, the substrate 6 may be a printed circuit board (PCB).

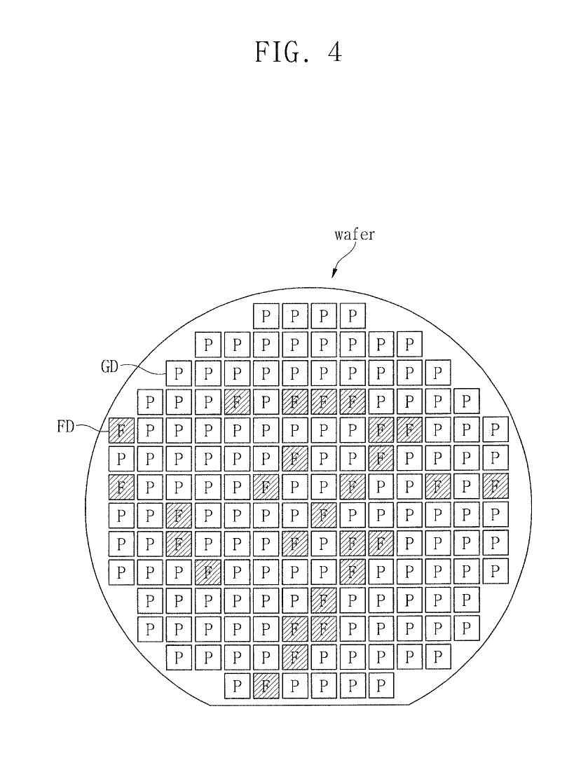

The buffer chip 5 may be manufactured according to a DRAM manufacturing process used to form the first DRAM 1 to the fourth DRAM 4. In other words, the buffer chip 5 may be a failed DRAM chip left on a wafer in the process of manufacturing a DRAM. Thus, additional costs may not be incurred to separately manufacture the buffer chip 5. The buffer chip 5 will be described in detail with reference to FIGS. 4 to 6 below.

FIG. 4 illustrates a wafer including the memory device 10 of FIG. 3, according to an exemplary embodiment of the inventive concept.

Referring to FIGS. 3 and 4, a wafer used to manufacture the memory device 10 is illustrated. In an exemplary embodiment of the inventive concept, the memory device 10 may be a DRAM.

On the wafer, ‘good’ dies (GDs) may be packaged as a DRAM, and ‘failed’ dies (FDs) may be discarded.

In general, a wafer has a yield of about 90% to manufacture a DRAM. Thus, the FDs that are discarded may be about 10% of the wafer. In the memory device 10 in accordance with an exemplary embodiment of the inventive concept, FDs are used as a buffer chip 5.

In a DRAM, most FDs are due to defective memory cells. This is because the rate of errors in the DRAM is proportional to a chip size of the DRAM. Thus, in/out buffers of most FDs may operate normally. In other words, the normally operable in/out buffers of the FDs may be used as the buffer chip 5 in accordance with an exemplary embodiment of the inventive concept.

For example, in accordance with an exemplary embodiment of the inventive concept, a data buffer of a DRAM may be configured to be used as a DRAM when the DRAM normally operates, and to be used as a buffer chip when the DRAM does not normally operate. In addition, the settings of a DRAM may be changed such that the DRAM functions as a buffer chip when the DRAM has failed. A mode register set (MRS) or an e-fuse may be used to perform such a change.

FIG. 5 is a block diagram of a memory system 1000 in accordance with an exemplary embodiment of the inventive concept.

Referring to FIGS. 3 and 5, the memory system 1000 includes a memory module 100, and a memory controller 150 configured to control the memory module 100. In an exemplary embodiment of the inventive concept, the memory system 1000 may further include a plurality of memory modules 100.

In general, the memory module 100 may include eight or sixteen memory devices 10. The memory module 100 in accordance with an exemplary embodiment of the inventive concept may be an LRDIMM. In this case, the memory module 100 may include sixteen memory devices 10.

The memory devices 10 may include a first DRAM 1 to a fourth DRAM 4, and a buffer chip 5 configured to connect the first DRAM 1 to the fourth DRAM 4. The buffer chip 5 may be connected to the memory controller 150 outside the memory module 100.

The first DRAM 1 to the fourth DRAM 4 and the buffer chip 5 may be manufactured using the same DRAM manufacturing process. Thus, the first DRAM 1 to the fourth DRAM 4, and the buffer chip 5 may include the same input/output (IO) port. In an exemplary embodiment of the inventive concept, in/out buffers of the first DRAM 1 to the fourth DRAM 4 and the buffer chip 5 may be 8 bits long. In other words, the first DRAM 1 to the fourth DRAM 4 and the buffer chip 5 may each include first to eighth data queues DQ1 to DQ8.

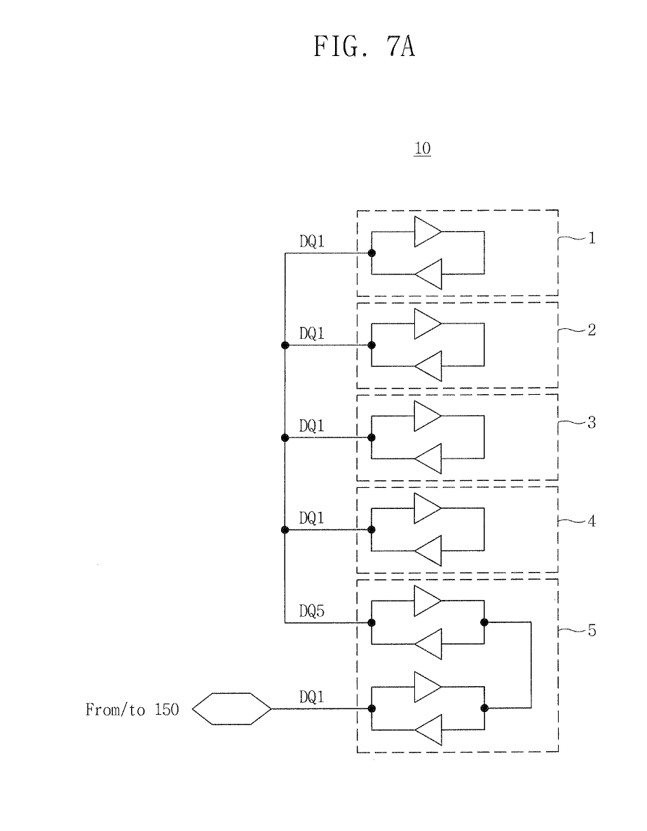

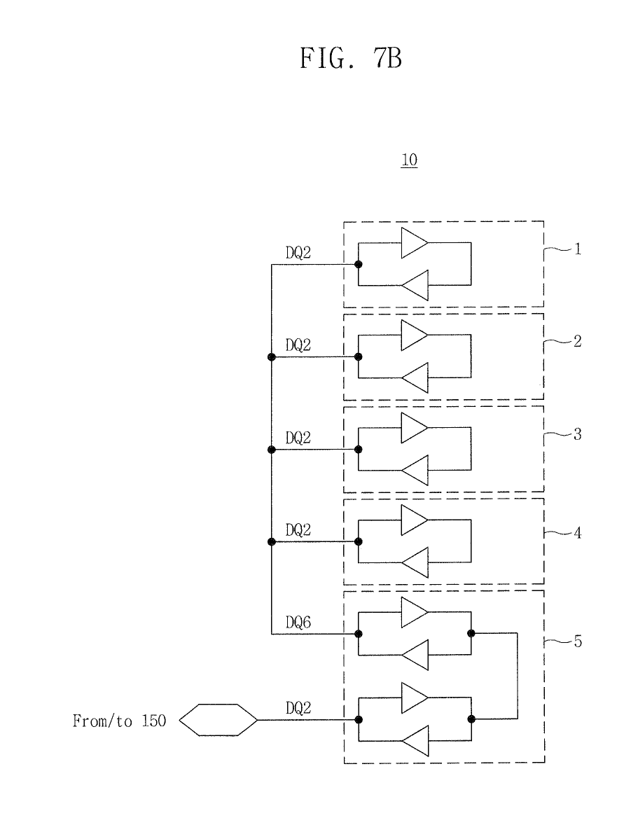

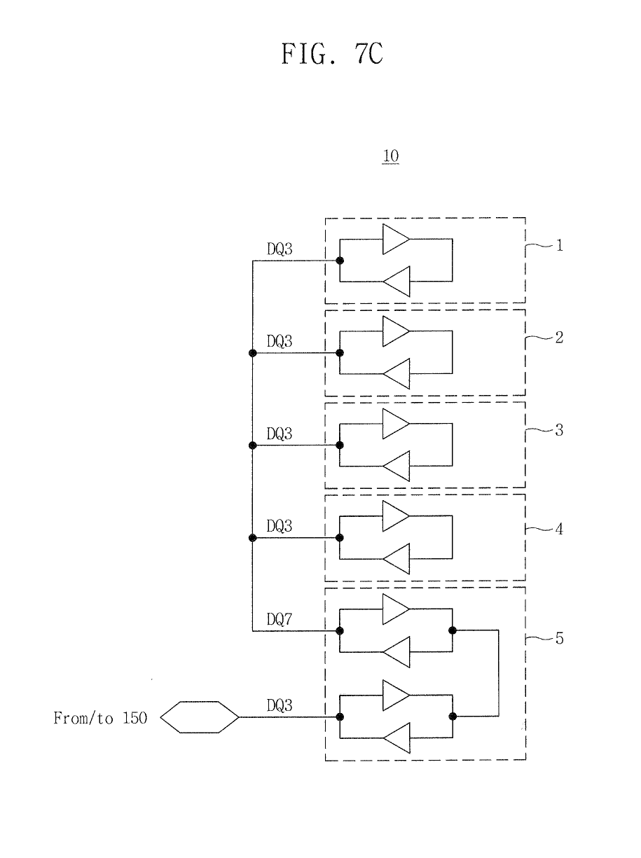

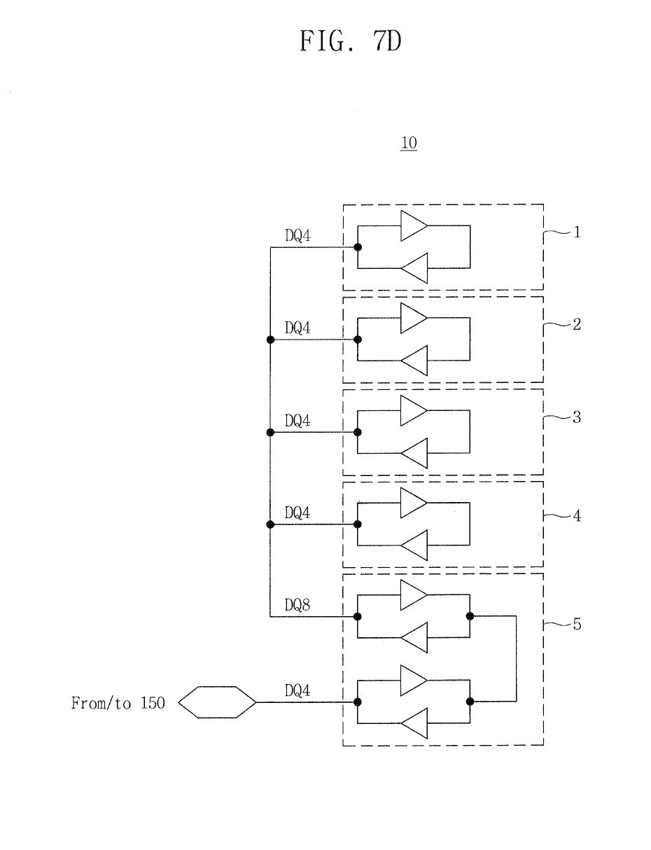

The first to fourth data queues DQ1 to DQ4 of the respective first to fourth DRAMs 1 to 4 may be connected to the fifth to eighth data queues DQ5 to DQ8 of the buffer chip 5, respectively. In addition, the first to fourth data queues DQ1 to DQ4 of the buffer chip 5 may be connected to the memory controller 150. A connection of the first DRAM 1 to the fourth DRAM 4 and the buffer chip 5 will be described in detail with reference to FIGS. 7A to 7D.

The memory system 1000 in accordance with an exemplary embodiment of the inventive concept may reduce a capacitive load caused by a plurality of memory modules 100. In addition, the memory system 1000 may provide the same latency between all ranks. Thus, a time delay does not have to be controlled to compensate for a skew between the memory modules 100.

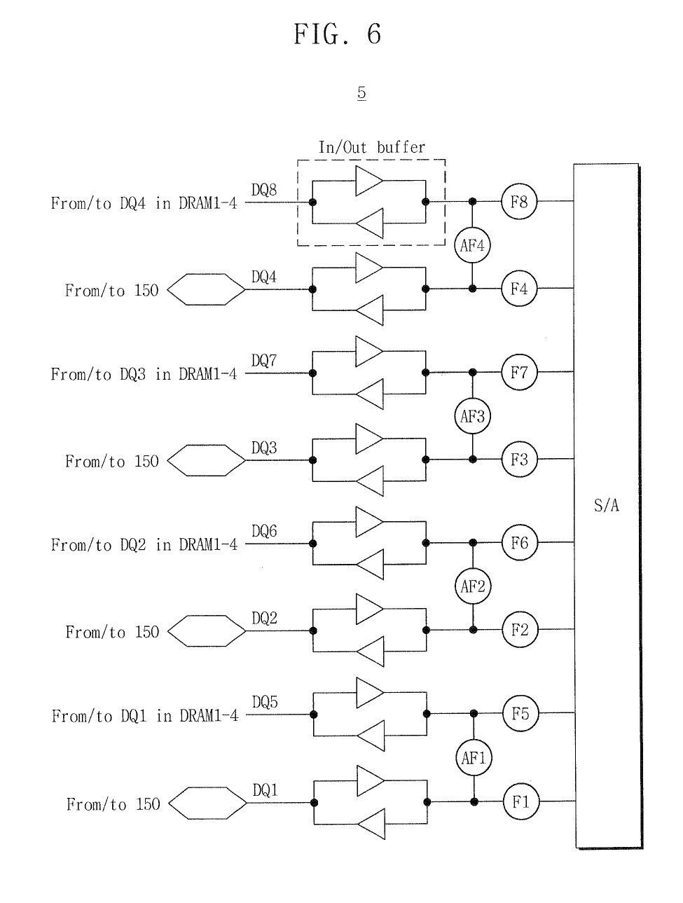

FIG. 6 is a diagram of the buffer chip 5 of FIG. 5, according to an exemplary embodiment of the inventive concept.

Referring to FIGS. 5 and 6, the buffer chip 5 may include eight in/out buffers. The eight in/out buffers may each include an e-fuse configured to electrically isolate a failed memory cell region.

A first DRAM 1 to a fourth DRAM 4 may each include eight in/out buffers. The eight in/out buffers included in each of the first DRAM 1 to the fourth DRAM 4 may each include or be connected to an e-fuse configured to electrically isolate a failed memory cell region.

Specifically, a first e-fuse F1 may be connected between an in/out buffer connected to a first data queue DQ1 and a sense amplifier S/A.

Similarly, a second e-fuse F2 may be connected between an in/out buffer connected to a second data queue DQ2 and the sense amplifier S/A. A third e-fuse F3 may be connected between an in/out buffer connected to a third data queue DQ3 and the sense amplifier S/A. A fourth e-fuse F4 may be connected between an in/out buffer connected to a fourth data queue DQ4 and the sense amplifier S/A. A fifth e-fuse F5 may be connected between an in/out buffer connected to a fifth data queue DQ5 and the sense amplifier S/A. A sixth e-fuse F6 may be connected between an in/out buffer connected to a sixth data queue DQ6 and the sense amplifier S/A. A seventh e-fuse F7 may be connected between an in/out buffer connected to a seventh data queue DQ7 and the sense amplifier S/A. An eighth e-fuse F8 may be connected between an in/out buffer connected to an eighth data queue DQ8 and the sense amplifier S/A.

The buffer chip 5 may further include an anti-fuse to connect each of the first to fourth DRAMs 1 to 4 and the memory controller 150.

Specifically, a first anti-fuse AF1 may be connected between the in/out buffers connected to the first and fifth data queues DQ1 and DQ5. The first anti-fuse AF1 may electrically connect the in/out buffers connected to the first and fifth data queues DQ1 and DQ5.

A second anti-fuse AF2 may be connected between the in/out buffers connected to the second and sixth data queues DQ2 and DQ6. The second anti-fuse AF2 may electrically connect the in/out buffers connected to the second and sixth data queues DQ2 and DQ6.

A third anti-fuse AF3 may be connected between the in/out buffers connected to the third and seventh data queues DQ3 and DQ7. The third anti-fuse AF3 may electrically connect the in/out buffers connected to the third and seventh data queues DQ3 and DQ7.

A fourth anti-fuse AF4 may be connected between the in/out buffers connected to the fourth and eighth data queues DQ4 and DQ8. The fourth anti-fuse AF4 may electrically connect the in/out buffers connected to the fourth and eighth data queues DQ4 and DQ8.

In addition, the first to fourth data queues DQ1 to DQ4 of the buffer chip 5 may be connected to the memory controller 150.

FIGS. 7A to 7D are diagrams illustrating a data input/output structure of the memory device 10 of FIG. 4, according to an exemplary embodiment of the inventive concept.

Referring to FIGS. 7A to 7D, in the buffer chip 5, first to fourth data queues DQ1 to DQ4 may be connected to the memory controller 150, and fifth to eighth data queues DQ5 to DQ8 may be connected to data queues DQ1 to DQ4 of first to fourth DRAMs 1 to 4, respectively.

Specifically, the fifth data queue DQ5 of the buffer chip 5 may be connected to the first data queue DQ1 of each of the first to fourth DRAMs 1 to 4. The sixth data queue DQ6 of the buffer chip 5 may be connected to the second data queue DQ2 of each of the first to fourth DRAMs 1 to 4. The seventh data queue DQ7 of the buffer chip 5 may be connected to the third data queue DQ3 of each of the first to fourth DRAMs 1 to 4. The eighth data queue DQ8 of the buffer chip 5 may be connected to the fourth data queue DQ4 of each of the first to fourth DRAMs 1 to 4.

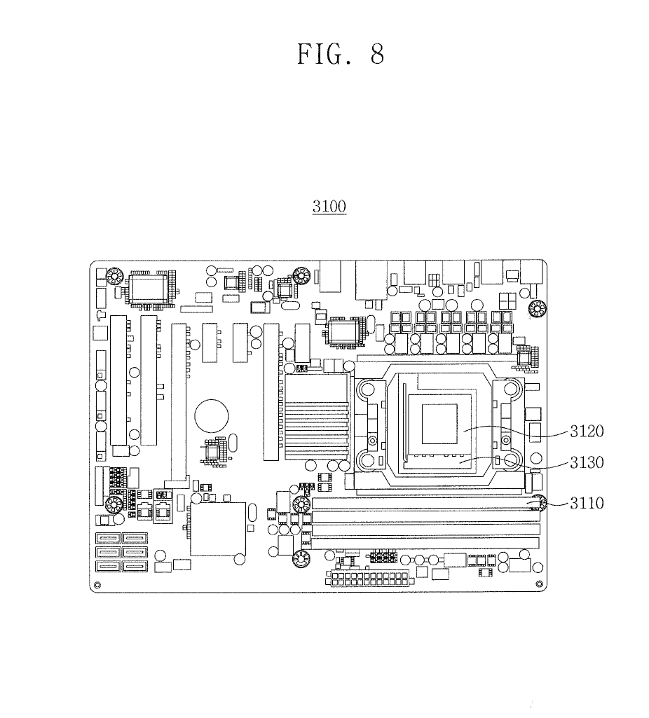

FIG. 8 is a diagram of a main board 3100 including the memory module 100 of FIG. 1 in accordance with an exemplary embodiment of the inventive concept.

Referring to FIGS. 1 and 8, the main board 3100 includes a plurality of slots 3110 into which the plurality of memory modules 100 are inserted.

The main board 3100 may further include a central processing unit (CPU) 3120 configured to access the plurality of memory modules 100, and a CPU socket 3130 into which the CPU 3120 is mounted.

The main board 3100, which may be a motherboard of a computer, contains circuitry for the CPU 3120 and other components mounted thereon or not, as well as the slots 3110 for accepting additional circuitry.

In an exemplary embodiment of the inventive concept, a memory controller (not shown) configured to control the memory modules 100 may be a part of the CPU 3120, or may be a chip installed separately from the CPU 3120.

When the CPU 3120 accesses the plurality of memory modules 100, latencies between the plurality of memory modules 100 or between ranks may be the same.

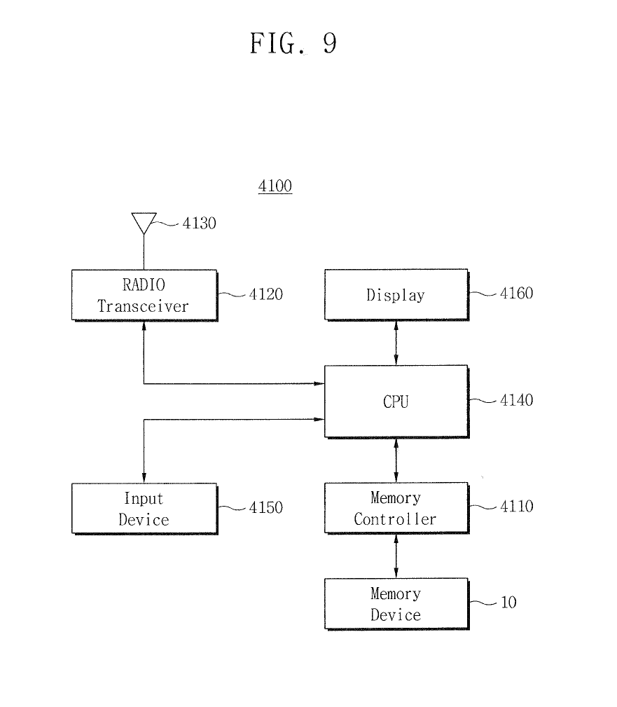

FIG. 9 is a block diagram of a computer system 4100 including the memory device 10 of FIG. 3 in accordance with an exemplary embodiment of the inventive concept.

Referring to FIG. 9, the computer system 4100 includes a memory device 10, a memory controller 4110 configured to control the memory device 10, a radio transceiver 4120, an antenna 4130, a CPU 4140, an input device 4150, and a display unit 4160.

The radio transceiver 4120 may transmit or receive a radio signal via the antenna 4130. For example, the radio transceiver 4120 may transform a radio signal received via the antenna 4130 to be processed by the CPU 4140.

Thus, the CPU 4140 may process a signal output from the radio transceiver 4120, and transmit the processed signal to the display unit 4160. In addition, the radio transceiver 4120 may transform a signal output from the CPU 4140 into a radio signal, and output the radio signal to an external device (not shown) via the antenna 4130.

The input device 4150 is a device via which a control signal for controlling an operation of the CPU 4140 or data that is to be processed by the CPU 4140 is input, and may be a pointing device such as a touch pad and a computer mouse, a keypad, or a keyboard.

In an exemplary embodiment of the inventive concept, the memory controller 4110 configured to control an operation of the memory device 10 may be a part of the CPU 4140, or may be a chip installed separately from the CPU 4140.

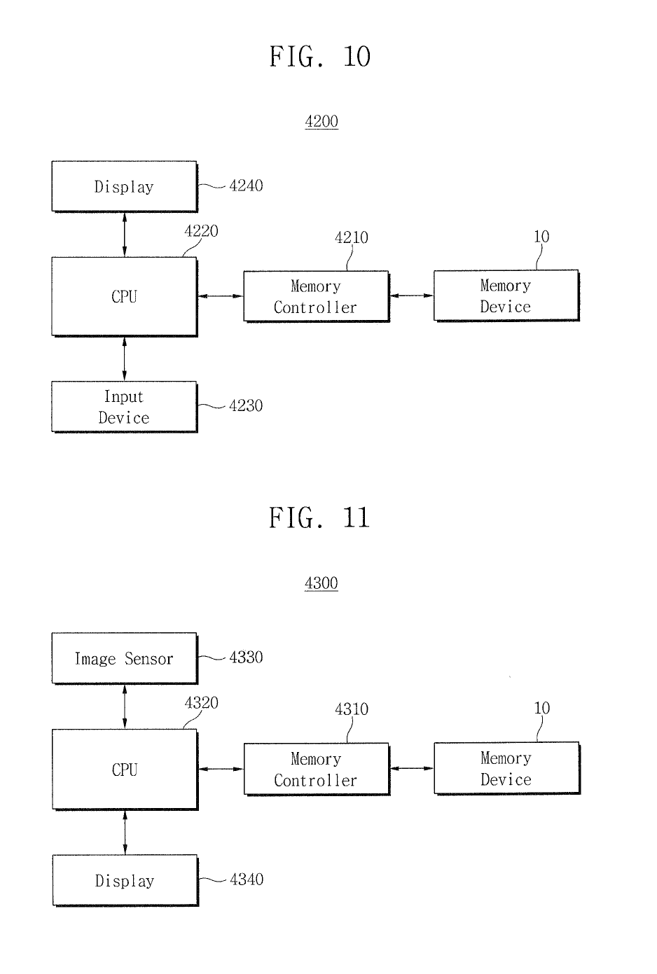

FIG. 10 is a block diagram of a computer system 4200 including the memory device 10 of FIG. 3 in accordance with an exemplary embodiment of the inventive concept.

Referring to FIG. 10, the computer system 4200 may be a personal computer (PC), a network server, a tablet PC, a net-book, an e-reader, a personal digital assistant (PDA), a portable multimedia player (PMP), an MP3 player, or an MP4 player.

The computer system 4200 includes a memory controller 4210 configured to control a memory device 10 and a data processing operation of the memory device 10, a CPU 4220, an input device 4230, and a display unit 4240.

The CPU 4220 may display data stored in the memory device 10 on the display unit 4240, based on data input via the input device 4230. For example, the input device 4230 may be a pointing device such as a touch pad and a computer mouse, a keypad, or a keyboard. The CPU 4220 may control overall operations of the computer system 4200 and an operation of the memory controller 4210.

In an exemplary embodiment of the inventive concept, the memory controller 4210 configured to control an operation of the memory device 10 may be a part of the CPU 4220, or may be a chip installed separately from the CPU 4220.

FIG. 11 is a block diagram of a computer system 4300 including the memory device 10 of FIG. 3 in accordance with an exemplary embodiment of the inventive concept.

Referring to FIG. 11, the computer system 4300 may be an image processing device (e.g., a digital camera), a mobile phone, a smart phone, or a tablet PC to which a digital camera is attached.

The computer system 4300 includes a memory device 10, and a memory controller 4310 configured to control a data processing operation (e.g., a write or read operation) of the memory device 10. The computer system 4300 may further include a CPU 4320, an image sensor 4330, and a display unit 4340.

The image sensor 4330 of the computer system 4300 transforms an optical image into digital signals, and transmits the digital signals to the CPU 4320 or the memory controller 4310. Under control of the CPU 4320, the digital signals may be displayed on the display unit 4340 or stored in the memory device 10 via the memory controller 4310.

In addition, data stored in the memory device 10 may be displayed on the display unit 4340, under control of the CPU 4320 or the memory controller 4310.

In an exemplary embodiment of the inventive concept, the memory controller 4310 configured to control an operation of the memory device 10 may be a part of the CPU 4320, or may be a chip installed separately from the CPU 4320.

An exemplary embodiment of the inventive concept may be applied to a memory module, a regular operating speed of which is guaranteed, and a mobile memory system including the memory module.

A memory module in accordance with an exemplary embodiment of the inventive concept is capable of providing the same latency between ranks, and reducing the capacitive load effect.

In addition, a memory system in accordance with an exemplary embodiment of the inventive concept includes a memory module capable of providing the same latency between ranks, and reducing the capacitive load effect.

While the inventive concept has been shown and described with reference to exemplary embodiments thereof, it will be apparent to those of ordinary skill in the art that various changes in form and detail may be made thereto without departing from the spirit and scope of the present inventive concept as defined by the following claims.

What is claimed is:

1. A memory device, comprising:
a plurality of memory chips; and
a buffer chip connected to the plurality of memory chips,
wherein the plurality of memory chips and the buffer chip are disposed in a stack,
a first input/output (IO) port of the buffer chip is connected in series to an external device, and
a second IO port of the buffer chip is connected in parallel to IO ports of each of the plurality of memory chips.

2. The memory device of claim 1, wherein at least one of the memory chips comprises a dynamic random access memory (DRAM),
wherein the DRAM and the buffer chip are memory chips manufactured according to the same memory manufacturing process, and
the buffer chip has a failed memory cell region.

3. The memory device of claim 2, wherein the buffer chip comprises eight IO buffers,
wherein each of the eight IO buffers is connected to an e-fuse configured to electrically isolate the failed memory cell region.

4. The memory device of claim 3, wherein at least one of the memory chips comprises first to eighth data queues each connected to a respective one of eight IO buffers of the memory chip, and the buffer chip comprises first to eighth data queues each connected to a respective one of the eight IO buffers of the buffer chip.

5. The memory device of claim 4, wherein the external device comprises a memory controller,
the first to fourth data queues of the buffer chip are connected to the memory controller,
the fifth data queue of the buffer chip is connected to a first data queue of each of the plurality of memory chips,
the sixth data queue of the buffer chip is connected to a second data queue of each of the plurality of memory chips,
the seventh data queue of the buffer chip is connected to a third data queue of each of the plurality of memory chips, and
the eighth data queue of the buffer chip is connected to a fourth data queue of each of the plurality of memory chips.

6. The memory device of claim 5, wherein the buffer chip further comprises:
a first anti-fuse configured to electrically connect the IO buffers of the buffer chip connected to the first and fifth data queues of the buffer chip;
a second anti-fuse configured to electrically connect the IO buffers of the buffer chip connected to the second and sixth data queues of the buffer chip;
a third anti-fuse configured to electrically connect the IO buffers of the buffer chip connected to the third and seventh data queues of the buffer chip; and
a fourth anti-fuse configured to electrically connect the IO buffers of the buffer chip connected to the respective fourth and eighth data queues of the buffer chip.

7. The memory device of claim 3, wherein the IO buffers of the buffer chip are normally operable.

8. The memory device of claim 1, wherein each of the plurality of memory chips is connected to the external device via the buffer chip.

9. A memory module including a plurality of memory devices, wherein at least one of the plurality of memory devices comprises:
a plurality of memory chips; and
a buffer chip connected to the plurality of memory chips,
wherein the plurality of memory chips and the buffer chip are disposed in a stack,
a first input/output (IO) port of the buffer chip is connected in series to an external device, and
a second IO port of the buffer chip is connected in parallel to IO ports of each of the plurality of memory chips.

10. The memory device of claim 9, wherein at least one of the memory chips comprises a dynamic random access memory (DRAM),
the DRAM and the buffer chip are memory chips manufactured according to the same memory manufacturing process, and
the buffer chip has a failed memory cell region.

11. The memory device of claim 10, wherein the buffer chip comprises eight IO buffers,
wherein each of the eight IO buffers is connected to an e-fuse configured to electrically isolate the failed memory cell region.

12. The memory device of claim 11, wherein at least one of the memory chips comprises first to eighth data queues each connected to a respective one of eight IO buffers of the memory chip, and the buffer chip comprises first to eighth data queues each connected to a respective one of the eight IO buffers of the buffer chip.

13. The memory device of claim 12, wherein the external device comprises a memory controller,
the first to fourth data queues of the buffer chip are connected to the memory controller,
the fifth data queue of the buffer chip is connected to a first data queue of each of the plurality of memory chips,
the sixth data queue of the buffer chip is connected to a second data queue of each of the plurality of memory chips,
the seventh data queue of the buffer chip is connected to a third data queue of each of the plurality of memory chips, and
the eighth data queue of the buffer chip is connected to a fourth data queue of each of the plurality of memory chips.

14. The memory device of claim 9, wherein the memory device is a multi-chip package.

15. The memory device of claim 9, wherein the memory module comprises a registered dual in-line memory module (RDIMM) or a load-reduced dual in-line memory module (LRDIMM).

16. A memory device, comprising;
a stacked structured including a plurality of memory chips and a buffer chip,
wherein the buffer chip includes a first plurality of data queues configured to be connected to an external device and a second plurality of data queues connected to data queues of each of the plurality of memory chips.

17. The memory device of claim 16, wherein the external device is a memory controller.

18. The memory device of claim 16, wherein the memory chips include a dynamic random access memory.

19. The memory device of claim 16, wherein the second plurality of data queues of the buffer chip includes first to fourth data queues, and each of the first to fourth data queues is connected to a respective data queue of each of the plurality of memory devices.

20. The memory device of claim 16, wherein the buffer chip includes a failed memory cell region.
